(19) United States
(12) Patent Application Publication
(10) Pub. No.: US 2026/0164724 A1
(43) Pub. Date: Jun. 11, 2026

(54) SEMICONDUCTOR DEVICE AND METHOD OF MANUFACTURING THE SAME

(71) Applicant: Renesas Electronics Corporation, Tokyo (JP)

(72) Inventors: Yoshiyuki SATO, Tokyo (JP); Hiromichi TAKAOKA, Tokyo (JP)

(21) Appl. No.: 19/319,386

(22) Filed: Sep. 4, 2025

(30) Foreign Application Priority Data
Dec. 11, 2024 (JP) 2024-216995

(51) Int. Cl. H10D 30/68; H10B 41/10; H10B 41/35; H10D 30/01; H10D 62/10

(52) U.S. Cl. CPC H10D 30/68; H10B 41/10; H10B 41/35; H10D 30/027; H10D 30/0411; H10D 62/115

(57) ABSTRACT

A gate electrode is formed on a semiconductor substrate via a second gate insulating film, and a floating gate electrode is formed on the semiconductor substrate via a first gate insulating film. A second sidewall spacer is formed on a side surface of the gate electrode, and a first sidewall spacer is formed on a side surface of the floating gate electrode. A first insulating film made of silicon oxide covers the floating gate electrode, and a second insulating film made of silicon nitride covers the gate electrode, the floating gate electrode, the second sidewall spacer, the first sidewall spacer, and the first insulating film. The first insulating film is interposed between an upper surface of the floating gate electrode and the second insulating film. A density of the upper portion of the first insulating film BL is larger than that of the lower portion of the first insulating film.

### CROSS-REFERENCE TO RELATED APPLICATION

The disclosure of Japanese Patent Application No. 2024-216995 filed on Dec. 11, 2024, including the specification, drawings and abstract is incorporated herein by reference in its entirety.

### BACKGROUND

The present invention relates to a semiconductor device and a method of manufacturing the same, and is appropriately applicable to, for example, a semiconductor device including a nonvolatile memory and a method of manufacturing the same.

As the nonvolatile memory, a nonvolatile memory including a floating gate electrode has been known. The nonvolatile memory including the floating gate electrode stores information by accumulating charges in the floating gate electrode.

There is disclosed techniques listed below.

[Patent Document 1] Japanese Unexamined Patent Application Publication No. 2011-199124

The Patent Document 1 discloses a technique related to the nonvolatile memory including the floating gate electrode.

### SUMMARY

It is desirable to improve reliability of semiconductor devices each including the nonvolatile memory including the floating gate electrode.

Other objects and novel characteristics will become apparent from the description of the present specification and the accompanying drawings.

A semiconductor device according to one embodiment includes: a semiconductor substrate; a floating gate electrode formed on the semiconductor substrate via a first gate insulating film; a first sidewall spacer formed on a side surface of the floating gate electrode; and a first insulating film covering the floating gate electrode. The semiconductor device further includes a silicon nitride film covering the floating gate electrode, the first sidewall spacer, and the first insulating film. The first insulating film is made of silicon oxide. The first insulating film is interposed between an upper surface of the floating gate electrode and the silicon nitride film. A density of an upper portion of the first insulating film is higher than a density of a lower portion of the first insulating film.

According to one embodiment, reliability of the semiconductor device can be improved.

### BRIEF DESCRIPTIONS OF THE DRAWINGS

FIG. 1 is a cross-sectional view illustrating a principal part of a semiconductor device according to a first embodiment.

FIG. 2 is a cross-sectional view illustrating a principal part of the semiconductor device according to the first embodiment.

FIG. 3 is a cross-sectional view illustrating a principal part of a step of manufacturing the semiconductor device according to the first embodiment.

FIG. 4 is a cross-sectional view illustrating a principal part of a step of manufacturing the semiconductor device continued from FIG. 3.

FIG. 5 is a cross-sectional view illustrating a principal part of a step of manufacturing the semiconductor device continued from FIG. 4.

FIG. 6 is a cross-sectional view illustrating a principal part of a step of manufacturing the semiconductor device continued from FIG. 5.

FIG. 7 is a cross-sectional view illustrating a principal part of a step of manufacturing the semiconductor device continued from FIG. 6.

FIG. 8 is a cross-sectional view illustrating a principal part of a step of manufacturing the semiconductor device continued from FIG. 7.

FIG. 9 is a cross-sectional view illustrating a principal part of a step of manufacturing the semiconductor device continued from FIG. 8.

FIG. 10 is a cross-sectional view illustrating a principal part of a step of manufacturing the semiconductor device continued from FIG. 9.

FIG. 11 is a cross-sectional view illustrating a principal part of a step of manufacturing the semiconductor device continued from FIG. 10.

FIG. 12 is a cross-sectional view illustrating a principal part of a step of manufacturing the semiconductor device continued from FIG. 11.

FIG. 13 is a cross-sectional view illustrating a principal part of a step of manufacturing the semiconductor device continued from FIG. 12.

FIG. 14 is a cross-sectional view illustrating a principal part of a step of manufacturing the semiconductor device continued from FIG. 13.

FIG. 15 is a cross-sectional view illustrating a principal part of a step of manufacturing the semiconductor device continued from FIG. 14.

FIG. 16 is a cross-sectional view illustrating a principal part of a step of manufacturing the semiconductor device continued from FIG. 15.

FIG. 17 is a cross-sectional view illustrating a principal part of a step of manufacturing the semiconductor device continued from FIG. 16.

FIG. 18 is a cross-sectional view illustrating a principal part of a step of manufacturing the semiconductor device continued from FIG. 17.

FIG. 19 is a cross-sectional view illustrating a principal part of a semiconductor device according to a first examination example.

FIG. 20 is a cross-sectional view illustrating a principal part of the semiconductor device according to the first examination example.

FIG. 21 is a cross-sectional view illustrating a principal part of a semiconductor device according to a second embodiment.

FIG. 22 is a plan view illustrating a principal part of the semiconductor device according to the second embodiment.

FIG. 23 is a plan view illustrating a principal part of a semiconductor device according to a first modification example of the second embodiment.

FIG. 24 is a plan view illustrating a principal part of a semiconductor device according to a second modification example of the second embodiment.

FIG. 25 is a plan view illustrating a principal part of a semiconductor device according to a third modification example of the second embodiment.

FIG. 26 is a cross-sectional view illustrating a principal part of a semiconductor device according to a third embodiment.

FIG. 27 is a cross-sectional view illustrating a principal part of a semiconductor device according to a fourth embodiment.

FIG. 28 is a cross-sectional view illustrating a principal part of the semiconductor device according to the fourth embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments will be described in detail with reference to the accompanying drawings. Note that components having the same function are denoted with the same reference symbols throughout all the drawings for describing the embodiments, and the repetitive description thereof will be omitted. In addition, in the following embodiments, the description of the same or similar portions is not repeated in principle unless otherwise particularly required.

The hatching of even the cross-sectional views in the drawings for the embodiments may be omitted so as to make the drawings easy to see. Also, even the plan views may be hatched so as to make the drawings easy to see.

The “plan view” corresponds to a case of viewing from a plane substantially parallel to a main surface or a back surface of a semiconductor substrate SB. A “bottom surface” has the same meaning as a “lower surface.”

In the present application, metal oxide semiconductor field effect transistors (MOSFETs) include not only MOSFETs each using an oxide film as a gate insulating film but also MOSFETs each using an insulating film other than an oxide film as a gate insulating film.

### FIRST EMBODIMENT

### Configuration of Semiconductor Device

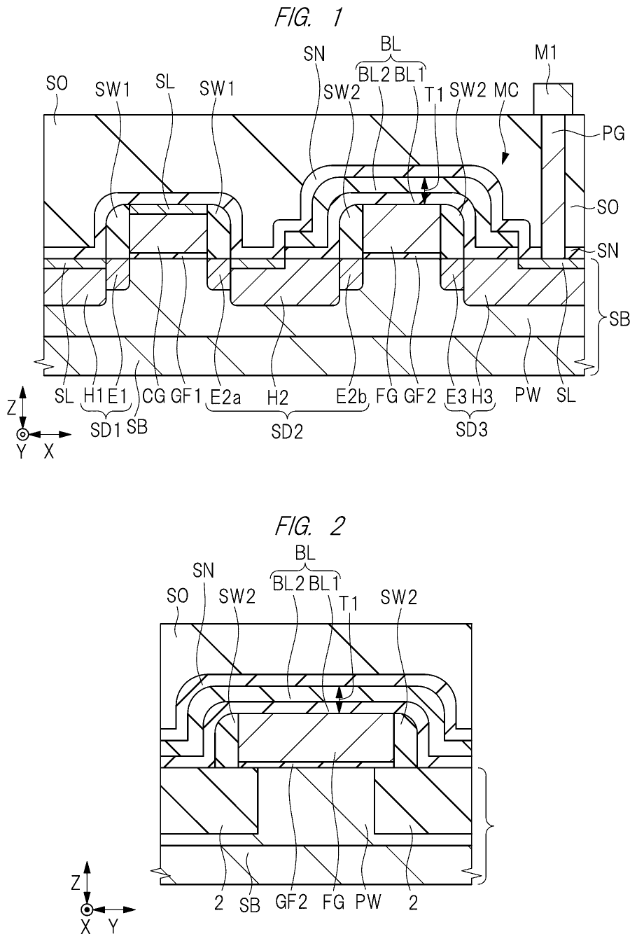

FIGS. 1 and 2 illustrate an X direction, a Y direction, and a Z direction. The X direction and the Y direction are substantially parallel to a main surface of the semiconductor substrate SB, and the Z direction is substantially perpendicular to the main surface of the semiconductor substrate SB. The X direction, the Y direction, and the Z direction are orthogonal to one another. The cross-sectional view of FIG. 1 is parallel to the X direction and the Z direction, and is perpendicular to the Y direction. The cross-sectional view of FIG. 2 is parallel to the Y direction and the Z direction, and is perpendicular to the X direction.

As illustrated in FIGS. 1 and 2, a semiconductor device according to a first embodiment includes the semiconductor substrate SB, an STI region 2, a p-type well PW, a control gate electrode CG, a floating gate electrode FG, a gate insulating film GF1, a gate insulating film GF2, an n-type semiconductor region SD1, an n-type semiconductor region SD2, an n-type semiconductor region SD3, a sidewall spacer SW1, and a sidewall spacer SW2. As illustrated in FIGS. 1 and 2, the semiconductor device according to the first embodiment further includes an insulating film BL, a metal silicide layer SL, an insulating film SN, an insulating film SO, a plug PG, and a wiring M1.

The semiconductor substrate SB is made of, for example, p-type monocrystalline silicon. The semiconductor substrate SB has a main surface and a back surface opposite the main surface.

The STI (shallow trench isolation) region 2 is made of an insulating film embedded in a trench formed in the semiconductor substrate SB. The STI region 2 can be regarded as an insulating region.

The p-type well PW, the n-type semiconductor region SD1, the n-type semiconductor region SD2, and the n-type semiconductor region SD3 are formed in the semiconductor substrate SB.

The control gate electrode CG is formed on the main surface of the semiconductor substrate SB (on the p-type well PW) via the gate insulating film GF1. Thus, the gate insulating film GF1 is interposed between the control gate electrode CG and the semiconductor substrate SB. The gate width direction of the control gate electrode CG is the Y direction, and the gate length direction of the control gate electrode CG is the X direction.

The floating gate electrode FG is formed on the main surface of the semiconductor substrate SB (on the p-type well PW) via the gate insulating film GF2. Thus, the gate insulating film GF2 is interposed between the floating gate electrode FG and the semiconductor substrate SB. The gate width direction of the floating gate electrode FG is the Y direction, and the gate length direction of the floating gate electrode FG is the X direction. The control gate electrode CG and the floating gate electrode FG are spaced apart from each other.

The sidewall spacer SW1 is formed as a sidewall insulating film on the side surface (sidewall) of the control gate electrode CG. The sidewall spacer SW2 is formed as a sidewall insulating film on the side surface (sidewall) of the floating gate electrode FG.

The control gate electrode CG and the floating gate electrode FG are adjacent to each other in the X direction. In plan view (specifically in the X direction), the control gate electrode CG, the n-type semiconductor region SD2, and the floating gate electrode FG are positioned between the n-type semiconductor region SD1 and the n-type semiconductor region SD3 while the n-type semiconductor region SD2 is positioned between the control gate electrode CG and the floating gate electrode FG. In plan view (specifically in the X direction), the control gate electrode CG is positioned between the n-type semiconductor region SD1 and the n-type semiconductor region SD2 while the floating gate electrode FG is positioned between the n-type semiconductor region SD2 and the n-type semiconductor region SD3.

The n-type semiconductor region SD1, the n-type semiconductor region SD2, and the n-type semiconductor region SD3 are formed in the p-type well PW. The n-type semiconductor region SD1 functions as a source or a drain. The n-type semiconductor region SD1 includes an n-type semiconductor region E1 and an n-type semiconductor region H1. The n-type impurity concentration of the n-type semiconductor region H1 is higher than the n-type impurity concentration of the n-type semiconductor region E1. Thus, the n-type semiconductor region SD1 has a lightly doped drain (LDD) configuration. The n-type semiconductor region E1 is positioned below the sidewall spacer SW1. The n-type semiconductor region E1 is positioned between the n-type semiconductor region H1 and the control gate electrode CG in plan view.

The n-type semiconductor region SD2 functions as a source or a drain. The n-type semiconductor region SD2 includes an n-type semiconductor region E2a, an n-type semiconductor region E2b, and an n-type semiconductor region H2. The n-type impurity concentration of the n-type semiconductor region H2 is higher than the n-type impurity concentration of the n-type semiconductor region E2a and is higher than the n-type impurity concentration of the n-type semiconductor region E2b. Thus, the n-type semiconductor region SD2 has the LDD configuration. The n-type semiconductor region E2a is positioned below the sidewall spacer SW1 while the n-type semiconductor region E2b is positioned below the sidewall spacer SW2. The n-type semiconductor region E2a is positioned between the n-type semiconductor region H2 and the control gate electrode CG while the n-type semiconductor region E2b is positioned between the n-type semiconductor region H2 and the floating gate electrode FG in plan view.

The n-type semiconductor region SD3 functions as a source or a drain. The n-type semiconductor region SD3 includes an n-type semiconductor region E3 and an n-type semiconductor region H3. The n-type impurity concentration of the n-type semiconductor region H3 is higher than the n-type impurity concentration of the n-type semiconductor region E3. Thus, the n-type semiconductor region SD3 has the LDD configuration. The n-type semiconductor region E3 is positioned below the sidewall spacer SW2. The n-type semiconductor region E3 is positioned between the n-type semiconductor region H3 and the floating gate electrode FG in plan view. Note that the n-type semiconductor region E3 is not formed in some cases.

The metal silicide layer SL is formed on each of the upper surface of the n-type semiconductor region H1, the upper surface of the n-type semiconductor region H2, the upper surface of the n-type semiconductor region H3, and the upper surface of the control gate electrode CG. The metal silicide layer SL is not formed on the floating gate electrode FG. The metal silicide layer SL is not formed on the upper surface of the n-type semiconductor region H2 in some cases.

The insulating film (silicon oxide film) BL is formed to cover at least the upper surface of the floating gate electrode FG, and is preferably formed to cover the floating gate electrode FG and the sidewall spacer SW2. The entire upper surface of the floating gate electrode FG is covered with the insulating film BL. The floating gate electrode FG is included in the insulating film BL in plan view. The control gate electrode CG is not covered with the insulating film BL. That is, the control gate electrode CG and the insulating film BL do not overlap each other in plan view.

The insulating film BL is made of a stacked film including an insulating film (silicon oxide film) BL1 and an insulating film (silicon oxide film) BL2 on the insulating film BL1. The insulating film BL1 is made of silicon oxide, and is formed by using a thermal chemical vapor deposition (thermal CVD) method. The insulating film BL2 is made of silicon oxide, and is formed by using a plasma chemical vapor deposition (plasma CVD) method. That is, the insulating film BL1 and the insulating film BL2 are both made of silicon oxide, but are different from each other in the film forming method. Since the insulating film BL1 is formed by using the thermal CVD while the insulating film BL2 is formed by using the plasma CVD, the density (atom density) of the insulating film BL1 is smaller than the density (atom density) of the insulating film BL2. The atom density described here is equivalent to the number of atoms per unit volume. The upper surface of the floating gate electrode FG is in contact with the insulating film BL1.

One of both ends of the insulating film BL in the X direction is positioned on the n-type semiconductor region H2 while the other thereof is positioned on the n-type semiconductor region H3. Thus, a part of the n-type semiconductor region H2 is covered with the insulating film BL, and the other part of the n-type semiconductor region H2 is not covered with the insulating film BL and is exposed from the insulating film BL. The metal silicide layer SL is formed on the n-type semiconductor region H2 exposed from the insulating film BL. The metal silicide layer SL is not formed on the n-type semiconductor region H2 covered with the insulating film BL. A part of the n-type semiconductor region H3 is covered with the insulating film BL, and the other part of the n-type semiconductor region H3 is not covered with the insulating film BL and is exposed from the insulating film BL. The metal silicide layer SL is formed on the n-type semiconductor region H3 exposed from the insulating film BL. The metal silicide layer SL is not formed on the n-type semiconductor region H3 covered with the insulating film BL.

The insulating film (silicon nitride film) SN is formed on the main surface of the semiconductor substrate SB to cover the control gate electrode CG, the floating gate electrode FG, the sidewall spacer SW1, the sidewall spacer SW2, the metal silicide layer SL, and the insulating film BL. The insulating film SO is formed on the insulating film SN.

The insulating film SN is made of silicon nitride. The thickness of the insulating film SN is smaller than the thickness of the insulating film SO. The insulating film SO is made of a different material from the insulating film SN, and is preferably made of silicon oxide. As the insulating film SO, a low dielectric constant (low-k) film with a lower dielectric constant than that of silicon oxide can be also used. A stacked film including the insulating film SN and the insulating film SO can function as an interlayer insulating film.

The insulating film BL is interposed between the upper surface of the floating gate electrode FG and the insulating film SN. Thus, the floating gate electrode FG is not in contact with the insulating film SN. The distance (gap) between the insulating film SN and the upper surface of the floating gate electrode FG in the Z direction is the same as the thickness T1 of the insulating film BL. The upper surface of the insulating film BL (the upper surface of the insulating film BL2) is in contact with the insulating film SN. The upper surface of the metal silicide layer SL on the control gate electrode CG is in contact with the insulating film SN. Thus, the distance between the floating gate electrode FG and the insulating film SN is larger than the distance between the metal silicide layer SL on the control gate electrode CG and the insulating film SN.

A conductive plug PG is formed in a contact hole penetrating through the insulating film SO and the insulating film SN. The wiring M1 is formed on the insulating film SO. The upper surface of the plug PG is in contact with the wiring M1.

The plug PG is arranged on each of the n-type semiconductor region H1, the n-type semiconductor region H3, and the control gate electrode CG. FIG. 1 illustrates the plug PG arranged on the n-type semiconductor region H3. The potential of the floating gate electrode FG is a floating potential, and thus, the plug PG is not arranged on the floating gate electrode FG.

Illustration and description for the configuration upper than the insulating film SO and the wiring M1 will be omitted.

A memory element (storage element, memory cell) MC of a nonvolatile memory is configured such that two MOSFETs that are a control transistor (select transistor) with the control gate electrode CG and a memory transistor (storage transistor) with the floating gate electrode FG are connected in series. The n-type semiconductor region SD1 functions as a drain region of the control transistor, the n-type semiconductor region SD3 functions as a source region of the memory transistor, and the n-type semiconductor region SD2 functions as both a source region of the control transistor and a drain region of the memory transistor. Alternatively, the n-type semiconductor region SD1 functions as the source region of the control transistor, the n-type semiconductor region SD3 functions as the drain region of the memory transistor, and the n-type semiconductor region SD2 functions as both the drain region of the control transistor and the source region of the memory transistor. Charges are accumulated or held in the floating gate electrode FG, thereby storing information into the memory element MC.

During a writing operation in the memory element MC, charges (electrons, here) are injected from the semiconductor substrate SB into the floating gate electrode FG. During an erasing operation in the memory element MC, the charges (electrons, here) accumulated in the floating gate electrode FG are moved outside the floating gate electrode FG. For example, the charges accumulated in the floating gate electrode FG are moved to an insulating film or the semiconductor substrate SB around the floating gate electrode FG. A threshold voltage of the memory transistor differs between when a state with the accumulation of charges (electrons, here) in the floating gate electrode FG and a state without the accumulation of charges (electrons, here) in the floating gate electrode FG, and thus, the information stored in the memory element MC can be read out because of the difference in the threshold voltage of the memory transistor.

FIG. 1 also illustrates one memory element MC. In a practical case, a plurality of the memory elements MC are arranged in an array pattern on the main surface of the semiconductor substrate SB.

The case where both the control transistor and the memory transistor are the n-channel MOSFETs has been described above. Both the control transistor and the memory transistor may be p-channel MOSFETs.

### Steps of Manufacturing Semiconductor Device

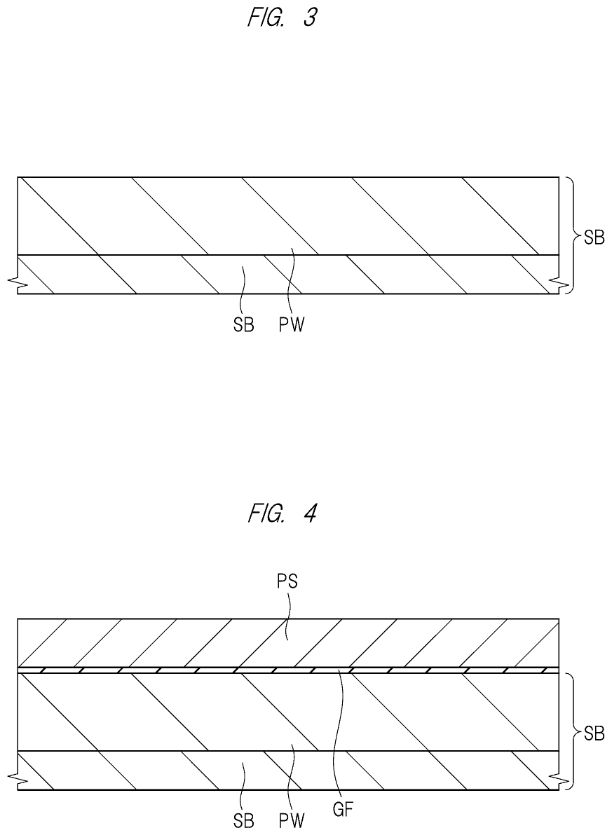

Each of FIGS. 3 to 18 illustrates the cross section corresponding to FIG. 1.

As illustrated in FIG. 3, the semiconductor substrate (semiconductor wafer) SB made of p-type monocrystalline silicon or the like is prepared.

The STI region 2 (see FIG. 2) defining an active region is then formed on the main surface of the semiconductor substrate SB by using STI.

A trench is formed in the semiconductor substrate SB, and then, an insulating film made of a silicon oxide film or the like is formed on the main surface of the semiconductor substrate SB to be embedded in the trench. Thereafter, the insulating film arranged outside the trench is removed by using a chemical mechanical polishing (CMP) method or the like. Thereby, the STI region 2 made of the insulating film embedded in the trench can be formed.

Next, as illustrated in FIG. 3, the p-type well PW is formed in the semiconductor substrate SB by using an ion implantation method. The p-type well PW is formed from the main surface of the semiconductor substrate SB to a predetermined depth.

Next, as illustrated in FIG. 4, the insulating film GF is formed on the main surface of the semiconductor substrate SB (on the upper surface of the p-type well PW). The insulating film GF is made of a silicon oxide film or the like, and can be formed by using a thermal oxidization method or the like.

Next, as illustrated in FIG. 4, a silicon film PS as a conductive film is formed on the main surface of the semiconductor substrate SB, in other words, on the insulating film GF. The silicon film PS is made of a doped polysilicon film, and can be formed by using a CVD method or the like.

Next, as illustrated in FIG. 5, the silicon film PS is patterned by using a photolithography technique and a dry etching technique, thereby forming the control gate electrode CG and the floating gate electrode FG. Each of the control gate electrode CG and the floating gate electrode FG is made of the patterned silicon film PS, and is formed on the main surface of the semiconductor substrate SB via the insulating film GF. The control gate electrode CG and the floating gate electrode FG are spaced apart from each other.

The insulating film GF remaining below the control gate electrode CG is the gate insulating film GF1, and the insulating film GF remaining below the floating gate electrode FG is the gate insulating film GF2. The control gate electrode CG is formed on the p-type well PW via the gate insulating film GF1. The floating gate electrode FG is formed on the p-type well PW via the gate insulating film GF2.

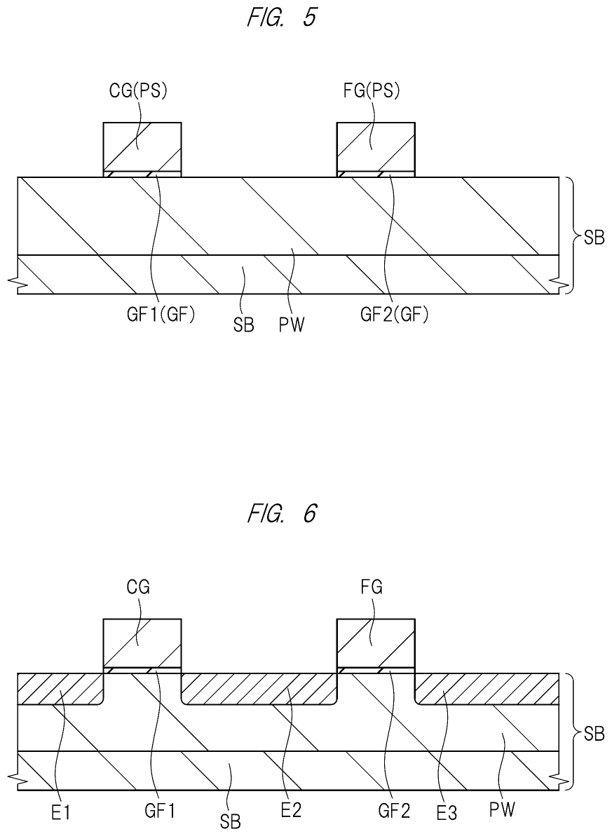

Next, as illustrated in FIG. 6, the n-type semiconductor region E1, the n-type semiconductor region E2, and the n-type semiconductor region E3 are formed in the semiconductor substrate SB by using an ion implantation method.

The n-type semiconductor region E1, the n-type semiconductor region E2 and the n-type semiconductor region E3 are formed in the p-type well PW. Each of the control gate electrode CG and the floating gate electrode FG can function as a mask for preventing ion implantation.

Thus, in the p-type well PW, the n-type semiconductor region E1 is formed so as to be self-aligned on one side surface of the control gate electrode CG. In the p-type well PW, the n-type semiconductor region E3 is formed so as to be self-aligned on one side surface of the floating gate electrode FG. In the p-type well PW, the n-type semiconductor region E2 is formed so as to be self-aligned on the other side surface of the control gate electrode CG and the other side surface of the floating gate electrode FG. The n-type semiconductor region E2 is formed between the control gate electrode CG and the floating gate electrode FG in plan view.

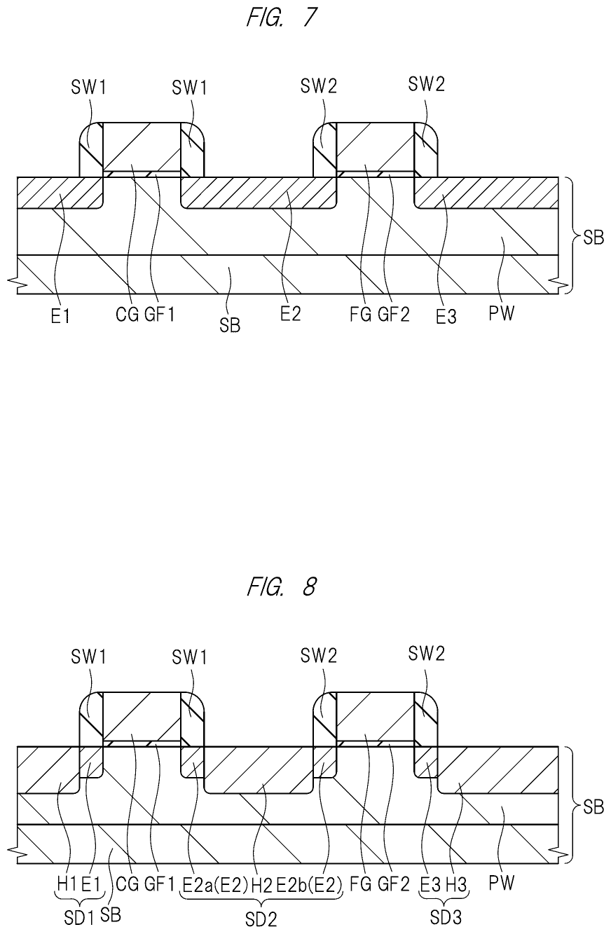

Next, as illustrated in FIG. 7, the sidewall spacer SW1 and the sidewall spacer SW2 are formed. The sidewall spacer SW1 is formed on the side surface (sidewall) of the control gate electrode CG. The sidewall spacer SW2 is formed on the side surface (sidewall) of the floating gate electrode FG.

For example, an insulating film (such as a silicon oxide film) is formed on the main surface of the semiconductor substrate SB to cover the control gate electrode CG and the floating gate electrode FG, and then, the insulating film is etched back by an anisotropic etching technique. Thereby, the sidewall spacer SW1 and the sidewall spacer SW2 can be made of the insulating films selectively remaining on the side surfaces of the control gate electrode CG and the floating gate electrode FG.

Next, as illustrated in FIG. 8, the n-type semiconductor region H1, the n-type semiconductor region H2 and the n-type semiconductor region H3 are formed in the semiconductor substrate SB by using an ion implantation method. Each of the control gate electrode CG, the sidewall spacer SW1, the floating gate electrode FG, and the sidewall spacer SW2 can function as a mask for preventing ion implantation.

Thus, in the p-type well PW, the n-type semiconductor region H1 is formed so as to be self-aligned on the sidewall spacer SW1 on one side surface of the control gate electrode CG. In the p-type well PW, the n-type semiconductor region H3 is formed so as to be self-aligned on the sidewall spacer SW2 on one side surface of the floating gate electrode FG. In the p-type well PW, the n-type semiconductor region H2 is formed so as to be self-aligned on the sidewall spacer SW1 on the other side surface of the control gate electrode CG and on the sidewall spacer SW2 on the other side surface of the floating gate electrode FG. The n-type semiconductor region E2 below the sidewall spacer SW1 is the n-type semiconductor region E2a, and the n-type semiconductor region E2 below the sidewall spacer SW2 is the n-type semiconductor region E2b.

Thereby, the n-type semiconductor region SD1 made of the n-type semiconductor region E1 and the n-type semiconductor region H1, the n-type semiconductor region SD2 made of the n-type semiconductor region E2a, the n-type semiconductor region E2b, and the n-type semiconductor region H2, and the n-type semiconductor region SD3 made of the n-type semiconductor region E3 and the n-type semiconductor region H3 are formed in the p-type well PW.

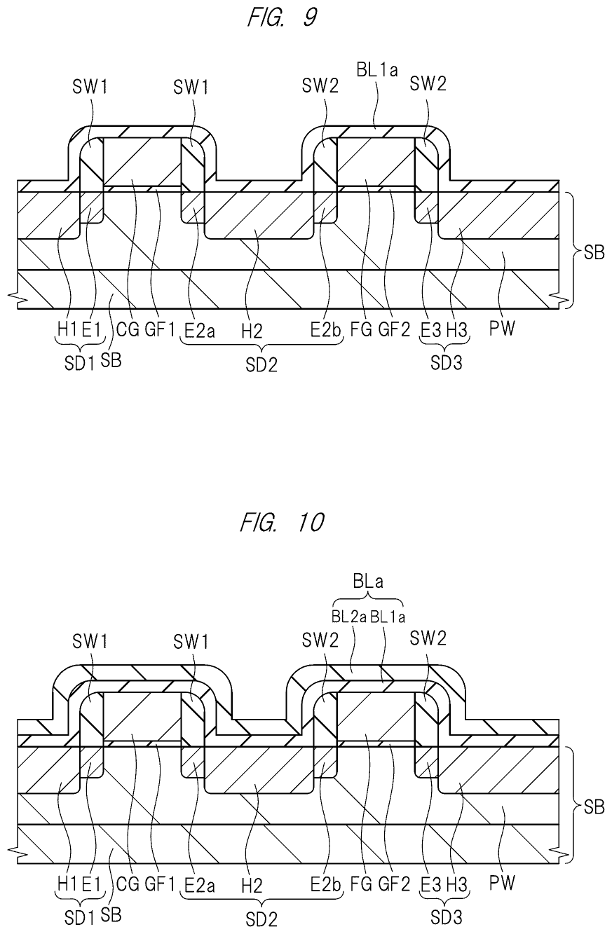

Next, as illustrated in FIG. 9, an insulating film BL1a is formed on the main surface of the semiconductor substrate SB to cover the control gate electrode CG, the floating gate electrode FG, the sidewall spacer SW1, the sidewall spacer SW2, the n-type semiconductor region H1, the n-type semiconductor region H2 and the n-type semiconductor region H3. The insulating film BL1a is made of silicon oxide, and can be formed by using a thermal CVD method. An atmospheric pressure CVD method is suitable as the thermal CVD method for forming the insulating film BL1a. The thickness of the formed insulating film BL1a is referred to as formation thickness of the insulating film BL1a.

Next, an activation annealing processing (thermal processing) is performed to activate impurities (p-type impurities and n-type impurities) introduced into the p-type well PW, the n-type semiconductor region E1, the n-type semiconductor region H1, the n-type semiconductor region E2 (E2a, E2b), the n-type semiconductor region H2, the n-type semiconductor region E3, the n-type semiconductor region H3 and the like. The activation annealing processing may adopt, for example, a lamp annealing processing.

Next, as illustrated in FIG. 10, an insulating film (silicon oxide film) BL2a is formed on the insulating film BL1a. The insulating film BL2a is made of silicon oxide, and can be formed by using a plasma CVD method. The thickness of the formed insulating film BL2a is referred to as formation thickness of the insulating film BL2a.

A stacked film including the insulating film BL1a and the insulating film BL2a on the insulating film BL1a is referred to as insulating film BLa. The insulating film BLa is formed on the main surface of the semiconductor substrate SB to cover the control gate electrode CG, the floating gate electrode FG, the sidewall spacer SW1, the sidewall spacer SW2, the n-type semiconductor region H1, the n-type semiconductor region H2, and the n-type semiconductor region H3.

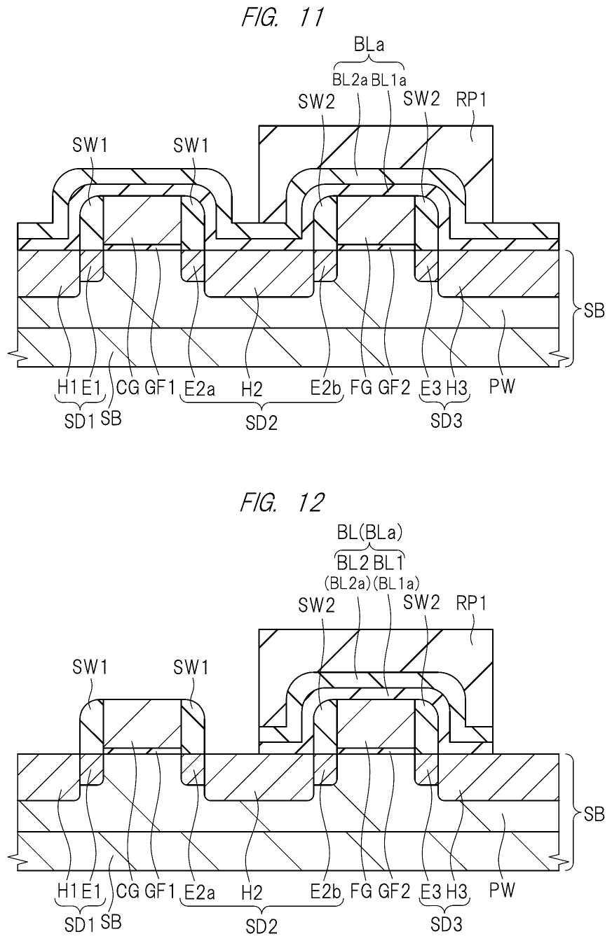

Next, as illustrated in FIG. 11, a photoresist pattern (mask layer) RP1 is formed on the insulating film BLa (in other words, on the insulating film BL2a) by using a photolithography technique.

The photoresist pattern RP1 includes the floating gate electrode FG in plan view. In other words, the entire floating gate electrode FG overlaps the photoresist pattern RP1 in plan view. In FIG. 11, the floating gate electrode FG and the sidewall spacer SW2 are included in the photoresist pattern RP1 in plan view. The control gate electrode CG and the sidewall spacer SW1 do not overlap the photoresist pattern RP1 in plan view.

Next, as illustrated in FIG. 12, the insulating film BLa exposed from the photoresist pattern RP1 is etched while the photoresist pattern RP1 is used as an etching mask. This etching step is referred to as etching step of FIG. 12. By the etching step of FIG. 12, the insulating film BLa exposed from the photoresist pattern RP1 is removed, and the insulating film BLa remains below the photoresist pattern RP1. The insulating film BL is made of the insulating film BLa remaining below the photoresist pattern RP1. The plane dimension and the plane position of the insulating film BL almost match the plane dimension and the plane position of the photoresist pattern RP1.

The insulating film BL is made of the patterned insulating film BLa. The insulating film BL1 configuring the insulating film BL is made of the patterned insulating film BL1a. The insulating film BL2 configuring the insulating film BL is made of the patterned insulating film BL2a. The thickness of the insulating film BL1 configuring the insulating film BL is almost equal to the formation thickness of the insulating film BL1a. The thickness of the insulating film BL2 configuring the insulating film BL is almost equal to the formation thickness of the insulating film BL2a.

The insulating film BL is formed to cover at least the floating gate electrode FG, and is preferably formed to cover the floating gate electrode FG and the sidewall spacer SW2. The control gate electrode CG is not covered with the insulating film BL. The entire floating gate electrode FG overlaps the insulating film BL while the control gate electrode CG does not overlap the insulating film BL in plan view.

By the etching step of FIG. 12, the insulating film BLa not covered with the photoresist pattern RP1 (in other words, the insulating film BLa not overlapping the photoresist pattern RP1 in plan view) is removed. Thus, by the etching step of FIG. 12, each of the upper surface of the control gate electrode CG, the upper surface of the n-type semiconductor region H1, the upper surface of the n-type semiconductor region H2 and the upper surface of the n-type semiconductor region H3 is exposed.

In the case of FIG. 12, the insulating film BL covers a part of the upper surface of the n-type semiconductor region H2 and a part of the upper surface of the n-type semiconductor region H3. In this case, the upper surface of the n-type semiconductor region H2 has a part covered with the insulating film BL and a part not covered with the insulating film BL, and the upper surface of the n-type semiconductor region H3 has a part covered with the insulating film BL and a part not covered with the insulating film BL.

Next, the photoresist pattern RP1 is removed.

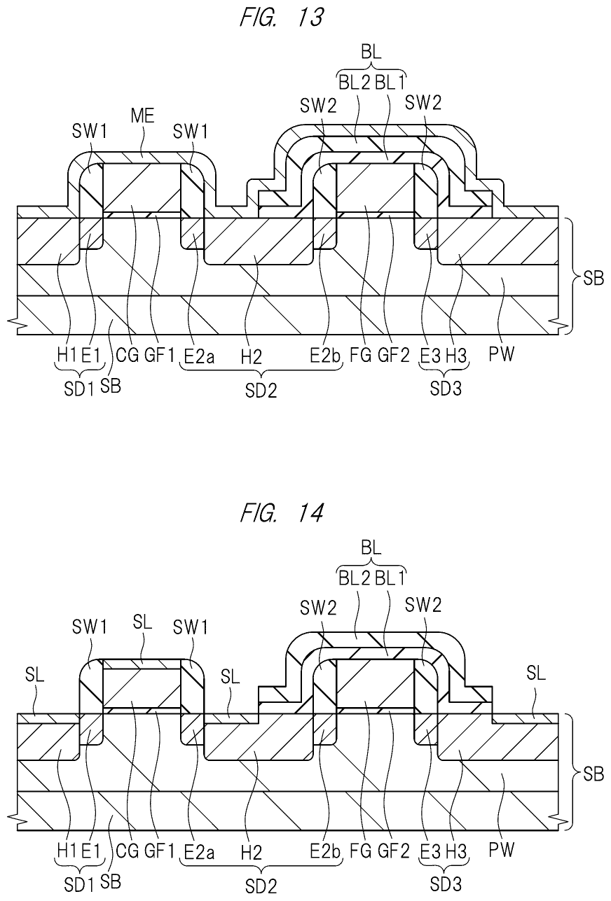

Next, as illustrated in FIG. 13, a metal film ME is formed on the (entire) main surface of the semiconductor substrate SB to cover the control gate electrode CG, the floating gate electrode FG, the sidewall spacer SW1, the sidewall spacer SW2, the n-type semiconductor region H1, the n-type semiconductor region H2, the n-type semiconductor region H3 and the insulating film BL. The metal film ME is made of, for example, a cobalt film, a nickel film, or a nickel-platinum alloy film, and can be formed by using a sputtering method or the like.

The metal film ME is in contact with the upper surface of the control gate electrode CG, the upper surface of the n-type semiconductor region H1, the upper surface of the n-type semiconductor region H2 and the upper surface of the n-type semiconductor region H3. The insulating film BL is interposed between the metal film ME and the floating gate electrode FG, and thus, the metal film ME is not in contact with the floating gate electrode FG.

Next, a thermal processing is performed on the semiconductor substrate SB, thereby making reaction between the metal film ME and the upper portions of the control gate electrode CG, the n-type semiconductor region H1, the n-type semiconductor region H2 and the n-type semiconductor region H3. Thereby, as illustrated in FIG. 14, the metal silicide layer SL as a layer of reaction between silicon and metal is formed on each of the control gate electrode CG, the n-type semiconductor region H1, the n-type semiconductor region H2 and the n-type semiconductor region H3. Since the insulating film BL is interposed between the metal film ME and the floating gate electrode FG, the metal film ME does not react with the floating gate electrode FG, and thus, the metal silicide layer SL is not formed on the floating gate electrode FG. That is, the step of forming the metal silicide layer SL is performed while the insulating film BL covers the floating gate electrode FG, and thus, the metal silicide layer SL is not formed on the floating gate electrode FG.

Next, the unreacted metal film ME is removed by wet etching or the like. FIG. 14 illustrates a state of the removal of the unreacted metal film ME. Thus, the metal silicide layer SL is formed by using a self aligned silicide (salicide) technique.

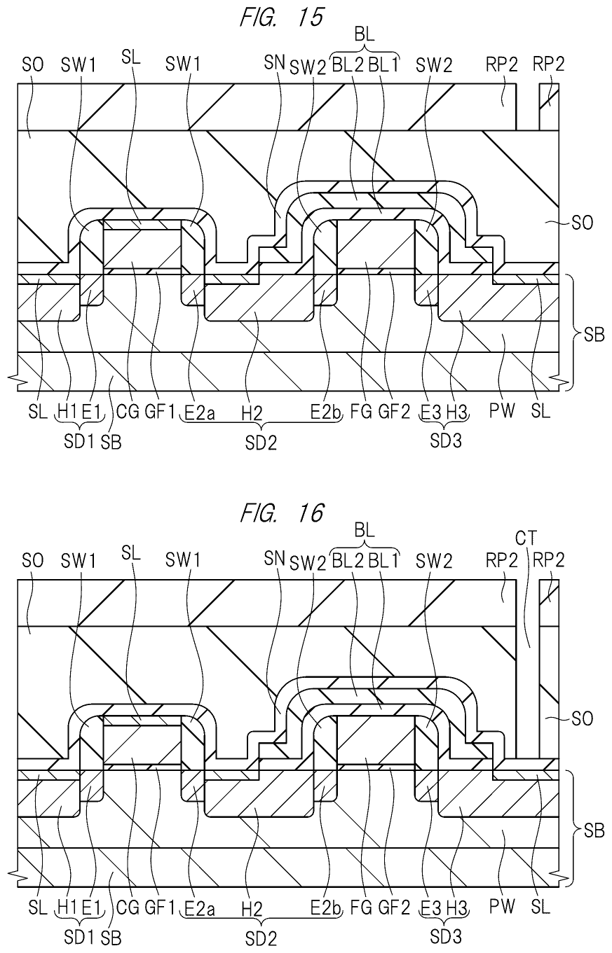

Next, as illustrated in FIG. 15, the insulating film (silicon nitride film) SN is formed on the main surface of the semiconductor substrate SB to cover each of the control gate electrode CG, the floating gate electrode FG, the sidewall spacer SW1, the sidewall spacer SW2, the n-type semiconductor region H1, the n-type semiconductor region H2, the n-type semiconductor region H3, the metal silicide layer SL and the insulating film BL. The insulating film SN is made of silicon nitride, and can be formed by using a CVD method or the like.

The insulating film BL is interposed between the floating gate electrode FG and the insulating film SN, and thus, the floating gate electrode FG is not in contact with the insulating film SN. The metal silicide layer SL on the control gate electrode CG, the metal silicide layer SL on the n-type semiconductor region H1, the metal silicide layer SL on the n-type semiconductor region H2 and the metal silicide layer SL on the n-type semiconductor region H3 are in contact with the insulating film SN.

Next, as illustrated in FIG. 15, the insulating film SO is formed on the insulating film SN. The thickness of the insulating film SO is larger than the thickness of the insulating film SN. The insulating film SO is made of a different material from the insulating film SN, and is preferably made of silicon oxide. As the insulating film SO, a low dielectric constant film can be also used. After the insulating film SO is formed, the upper surface of the insulating film SO is polished and flattened by using a chemical mechanical polishing (CMP) method or the like as needed.

Next, as illustrated in FIG. 15, a photoresist pattern (mask layer) RP2 is formed on the insulating film SO by using a photolithography technique.

Next, as illustrated in FIG. 16, the insulating film SO is etched while the photoresist pattern RP2 is used as an etching mask, thereby forming a contact hole CT in the insulating film SO. This etching is performed under the condition that the etching speed on the insulating film SN is smaller than the etching speed on the insulating film SO. Thus, the contact hole CT penetrating through the insulating film SO is formed, and the insulating film SN exposed from the contact hole CT functions as an etching stopper film. Therefore, the contact hole CT penetrates through the insulating film SO, but does not penetrate through the insulating film SN.

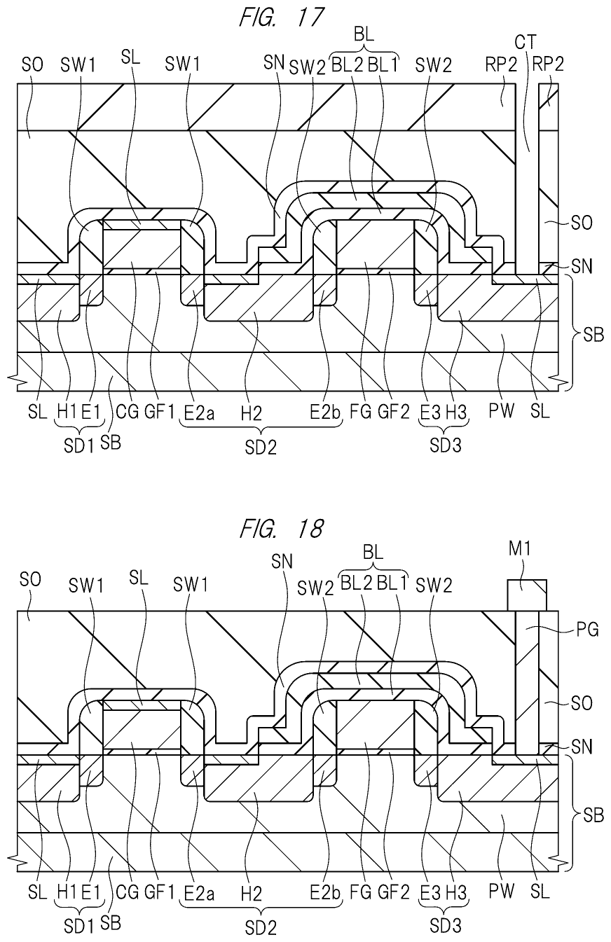

Next, as illustrated in FIG. 17, the insulating film SN exposed from the insulating film SO is etched while the photoresist pattern RP2 is used as an etching mask. This etching is performed under the condition that the etching speed on the insulating film SN is larger than the etching speed on the insulating film SO. Thus, the contact hole CT penetrates through the insulating film SN, and the metal silicide layer SL is exposed from the contact hole CT. Therefore, the contact hole CT penetrating through the insulating film SO and the insulating film SN is formed.

Next, as illustrated in FIG. 18, the conductive plug PG is formed in the contact hole CT.

For example, a barrier conductor film is formed on the bottom surface of the contact hole CT, the side surface of the contact hole CT, and the upper surface of the insulating film SO. Next, a main conductor film made of tungsten or the like is formed on the barrier conductor film to be embedded in the contact hole CT. Then, the main conductor film and the barrier conductor film arranged outside the contact hole CT are removed by a CMP method or the like. Thereby, the plug PG can be formed.

Next, as illustrated in FIG. 18, the plurality of wirings M1 are formed on the insulating film SO. For example, a conductive film is formed on the insulating film SO. Then, the conductive film is patterned by using a photolithography technique and an etching technique, thereby forming the plurality of wirings M1 made of the conductive film. As the wiring M1, an aluminum wiring is suitable. However, a wiring made of other metal material, such as tungsten wiring, can be also used. Alternatively, as the wiring M1, a copper wiring formed by damascene can be also used.

Illustration and description for steps of further forming an insulating film and a wiring on the wirings M1 and the insulating film SO will be omitted.

### Background of Examination

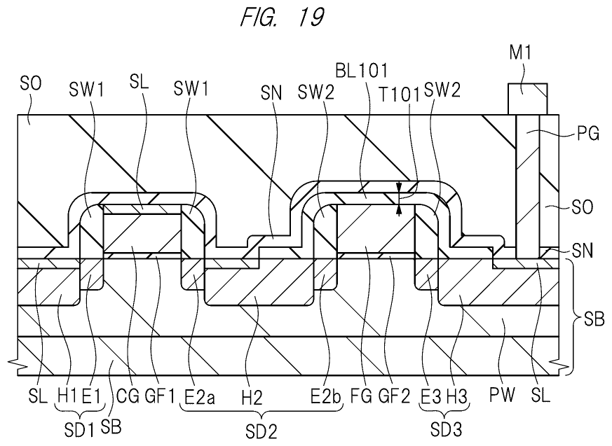

In a semiconductor device according to a first examination example illustrated in FIG. 19, an insulating film BL101 is formed instead of the insulating film BL.

The insulating film BL101 is a single-layer silicon oxide film. The insulating film BL101 is formed to cover the floating gate electrode FG and the sidewall spacer SW2. Thus, the insulating film BL101 (silicon oxide film) is interposed between the upper surface of the floating gate electrode FG and the insulating film SN (silicon nitride film). The control gate electrode CG is not covered with the insulating film BL101.

The present inventors have examined a nonvolatile memory including a floating gate electrode. The nonvolatile memory including the floating gate electrode can store information by accumulating charges in the floating gate electrode. Thus, it is important to improve the charge holding property of the nonvolatile memory, and it is necessary to prevent unintentional leakage of charges from the floating gate electrode to outside of the floating gate electrode.

An electric erasing operation and an erasing operation using ultraviolet light are used for the erasing operation in the nonvolatile memory. In the electric erasing operation, for example, a predetermined positive potential is applied to the n-type semiconductor region SD3 while the potential of the n-type semiconductor region SD1, the potential of the control gate electrode CG, and the potential of the p-type well PW are set at 0 V, thereby passing (tunnelling) and extracting the electrons accumulated in the floating gate electrode FG through the gate insulating film GF2 into the n-type semiconductor region SD3. Thereby, the number of electrons accumulated in the floating gate electrode FG decreases, and the memory element enters the erasing state. In the erasing operation using ultraviolet light, the floating gate electrode FG is irradiated with the ultraviolet light, thereby exciting the electrons accumulated in the floating gate electrode FG and moving the electrons accumulated in the floating gate electrode FG to outside the floating gate electrode FG. Thereby, the number of electrons accumulated in the floating gate electrode FG decreases, and the memory element enters the erasing state.

When the floating gate electrode FG is irradiated with the ultraviolet light during the erasing operation, the insulating film SN (silicon nitride film) above the floating gate electrode FG is also irradiated with the ultraviolet light. That is, the ultraviolet light having passed through the insulating film SO, the insulating film SN and the insulating film BL101 enters the floating gate electrode FG, and thus, the insulating film SN cannot avoid from being irradiated with the ultraviolet light.

According to the examination made by the present inventors, it is found out that the irradiation with the ultraviolet light onto the insulating film SN (silicon nitride film) causes a risk of decrease in the charge holding property of the nonvolatile memory.

A content of hydrogen in a silicon nitride film tends to be higher than a content of hydrogen in a silicon oxide film. Thus, it is conceivable that the irradiation with the ultraviolet light onto the insulating film SN (silicon nitride film) causes the insulating film SN to be a source of hydrogen ions, and promotes phenomenon of release of the hydrogen ions generated in the insulating film SN from the insulating film SN into the insulating film BL101 (silicon oxide film) and movement thereof in the insulating film BL101. It is conceivable that hydrogen bonds in the silicon nitride film (bonds between hydrogen atoms and silicon atoms, bonds between hydrogen atoms and nitrogen atoms, or bonds between hydrogen atoms) are cut by the irradiation with the ultraviolet light, thereby causing a movable state of the hydrogen atoms (hydrogen ions).

When the hydrogen ions moving in the insulating film BL101 reach the floating gate electrode FG, the charge (electron, here) holding property in the floating gate electrode FG may be influenced. That is, there is a risk of decrease in the effective amount of charges (electrons) accumulated in the floating gate electrode FG due to the bonding between the charges (electrons, here) accumulated in the floating gate electrode FG and the hydrogen ions present around the floating gate electrode FG. The unintentional decrease in the effective amount of charges (electrons) accumulated in the floating gate electrode FG decreases the charge holding property of the nonvolatile memory, and is to be prevented as much as possible.

### Principal Features and Effects

In the first embodiment, the insulating film BL is a stacked film which is made of silicon oxide and includes an insulating film (silicon oxide film) BL1 and an insulating film (silicon oxide film) BL2 on the insulating film BL1. The insulating film BL is formed to cover the upper surface of the floating gate electrode FG. Thus, the insulating film BL made of silicon oxide is interposed between the upper surface of the floating gate electrode FG and the insulating film SN (silicon nitride film). The control gate electrode CG is not covered with the insulating film BL.

In the description with reference to the first examination example, when the erasing operation using the ultraviolet light is used for the erasing operation in the nonvolatile memory, the irradiation with the ultraviolet light onto the insulating film SN (silicon nitride film) causes the insulating film SN to be the source of hydrogen, and generates the hydrogen ions in the insulating film SN. This promotes the phenomenon of the release of the hydrogen ions generated in the insulating film SN from the insulating film SN into the insulating film BL (silicon oxide film) and movement thereof in the insulating film BL.

The larger a thickness T1 of the insulating film BL is, the smaller a probability that the hydrogen ions having released from the insulating film SN into the insulating film BL and moved in the insulating film BL reach the floating gate electrode FG is. In other words, the larger a thickness T1 of the insulating film BL is, the more difficult the reaching of the hydrogen ions released from the insulating film SN into the insulating film BL to the floating gate electrode FG is.

Thus, the larger thickness T1 of the insulating film BL is preferable. Specifically, the thickness T1 of the insulating film BL in the manufactured semiconductor device is preferably 40 nm or more. That is, the thickness T1 of the insulating film BL after forming the insulating film SN is preferably 40 nm or more. In other words, the thickness T1 of the insulating film BL immediately before forming the insulating film SN is preferably 40 nm or more. Thereby, the reaching of the hydrogen ions, having released from the insulating film SN into the insulating film BL, to the floating gate electrode FG due to the irradiation with the ultraviolet light onto the insulating film SN can be suppressed or prevented. Thereby, the number of hydrogen ions around the floating gate electrode FG can be reduced, thereby suppressing or preventing the bonding between the charges (electrons, here) accumulated in the floating gate electrode FG and the hydrogen ions around the floating gate electrode FG. Consequently, the unintentional decrease in the effective amount of charges (electrons) accumulated in the floating gate electrode FG can be suppressed or prevented, and thus, the charge holding property of the nonvolatile memory can be improved. Therefore, reliability of the semiconductor device including the nonvolatile memory can be improved.

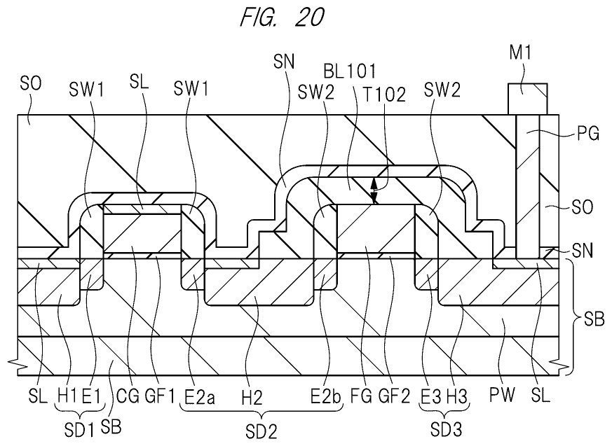

A case of the large thickness of the insulating film BL101 is referred to as a second examination example. The thickness T102 of the insulating film BL101 illustrated in FIG. 20 is larger than the thickness T101 of the insulating film BL101 illustrated in FIG. 19. The semiconductor device according to the second examination example illustrated in FIG. 20 is in the same configuration as the semiconductor device according to the first examination example illustrated in FIG. 19 except the thickness of the insulating film BL101.

In the second examination example illustrated in FIG. 20, because of the large thickness T102 of the insulating film BL101, the reaching of the hydrogen ions released from the insulating film SN into the insulating film BL101 due to the irradiation with the ultraviolet light onto the insulating film SN to the floating gate electrode FG can be suppressed or prevented. Consequently, the unintentional decrease in the effective amount of charges (electrons) accumulated in the floating gate electrode FG can be suppressed or prevented, and thus, the charge holding property of the nonvolatile memory can be improved.

However, the second examination example illustrated in FIG. 20 causes a risk of the following failures.

As a first case of the second examination example illustrated in FIG. 20, it is assumed that a single film made of silicon oxide formed by a thermal CVD method is applied for the insulating film BL101. The silicon oxide film formed by the thermal CVD method is smaller in density (atom density) and thus is larger in thermal shrinkage rate than the silicon oxide film formed by the plasma CVD method. Note that the smaller the density (atom density) of the silicon oxide film is, the larger the thermal shrinkage rate of the silicon oxide film is, and the easier the shrinkage of the silicon oxide film during the thermal processing is.

In the first case of the second examination example, since the thermal shrinkage rate of the insulating film BL101 formed by the thermal CVD method is large, a stress caused by thermal shrinkage of the insulating film BL101 is large. For example, when activation annealing is performed after forming the insulating film BL101 and before patterning the insulating film BL101, the insulating film BL101 thermally shrinks, thereby causing the stress in the semiconductor substrate SB. The large stress caused by the thermal shrinkage of the insulating film BL101 causes a risk of decrease in the reliability of the semiconductor device. For example, the large stress caused by the thermal shrinkage of the insulating film BL101 increases the number of crystal defects caused in the semiconductor substrate SB by the stress. Thus, it is desirable to suppress the stress caused by the thermal shrinkage of the insulating film BL101 as much as possible. The small thickness of the insulating film BL101 can decrease the stress caused by the thermal shrinkage of the insulating film BL101. However, the small thickness of the insulating film BL101 causes the decrease in the charge holding property of the nonvolatile memory as described with reference to the first examination example.

Accordingly, as a second case of the second examination example illustrated in FIG. 20, it is assumed that a single film made of silicon oxide formed by a plasma CVD method is applied for the insulating film BL101. The silicon oxide film formed by the plasma CVD method is larger in density (atom density) and thus is smaller in thermal shrinkage rate than the silicon oxide film formed by the thermal CVD method. Therefore, the second case is smaller in the stress caused by the thermal shrinkage of the insulating film BL101 than the first case.

However, the silicon oxide film formed by the plasma CVD method is lower in coverage than the silicon oxide film formed by the thermal CVD method. The silicon oxide film formed by the plasma CVD method is easier in the occurrence of the unintentional mixture of impurities than the silicon oxide film formed by the thermal CVD method. Thus, in the second case of the second examination example, the insulating film BL101 is more difficult to fill the gap between the control gate electrode CG and the floating gate electrode FG (between the sidewall spacer SW1 and the sidewall spacer SW2), and the insulating film BL101 is more difficult to be accurately formed. A plurality of MOSFETs are formed on the semiconductor substrate, and include a plurality of gate electrodes. The insulating film BL101 is more difficult to fill the gap between the adjacent gate electrodes, and the insulating film BL101 is more difficult to be accurately formed. Further, the second case of the second examination example has a concern about diffusion of the impurities of the insulating film BL101 into the floating gate electrode FG or the semiconductor substrate SB. The diffusion of the impurities of the insulating film BL101 into the floating gate electrode FG or the semiconductor substrate SB causes the risk of the decrease in reliability of the semiconductor device, and is desirable to be prevented as much as possible.

To the contrary, in the semiconductor device according to the first embodiment, the stacked film including the silicon oxide film (insulating film BL1) formed by the thermal CVD method and the silicon oxide film (insulating film BL2) formed by the plasma CVD method is applied for the insulating film BL. The insulating film BL1 is positioned below the insulating film BL2, and the insulating film BL2 is formed on the insulating film BL1.

It is assumed that the thickness T1 of the insulating film BL is equal to the thickness T102 of the insulating film BL101 according to the first case of the second examination example. The stress caused by the thermal shrinkage of the insulating film BL (BLa) in the first embodiment can be made smaller than the stress caused by the thermal shrinkage of the insulating film BL101 in the first case of the second examination example. This is because the insulating film BL (BLa) includes the insulating film BL2 (BL2a) formed by the plasma CVD method so that the insulating film BL2 (BL2a) is larger in density (atom density) and is smaller in thermal shrinkage rate than the insulating film BL1 (BL1a) formed by the thermal CVD method. Since the insulating film BL (BLa) includes the insulating film BL2 (BL2a) with the smaller density than that of the insulating film BL1 (BL1a), the thermal shrinkage of the entire insulating film BL (BLa) can be suppressed. Consequently, the stress caused by the thermal shrinkage of the insulating film BL (BLa) can be suppressed. Therefore, the reliability of the semiconductor device can be improved.

As described above, the silicon oxide film formed by the thermal CVD method is more excellent in coverage than the silicon oxide film formed by the plasma CVD method. In the first embodiment, the insulating film BLa is easier to fill the gap between the control gate electrode CG and the floating gate electrode FG (between the sidewall spacer SW1 and the sidewall spacer SW2), thereby more accurately forming the insulating film BLa, than the second case of the second examination example in which the entire insulating film BL101 is formed by the plasma CVD method, since the insulating film BLa includes the insulating film BL1a with more excellent coverage than that.

As described above, the silicon oxide film (insulating film BL2a) formed by the plasma CVD method is easier in the occurrence of the unintentional mixture of impurities than the silicon oxide film (insulating film BL1a) formed by the thermal CVD method. In other words, the silicon oxide film (insulating film BL1a) formed by the thermal CVD method is more difficult in the occurrence of the unintentional mixture of impurities than the silicon oxide film (insulating film BL2a) formed by the plasma CVD method, and thus, is more purified.

In the first embodiment, the insulating film BL2 (BL2a) is formed on the insulating film BL1 (BL1a), and thus, the insulating film BL2 (BL2a) is neither in contact with the floating gate electrode FG nor the semiconductor substrate SB. Therefore, the insulating film BL1 (BL1a) can suppress or prevent the diffusion of the impurities in the insulating film BL2 (BL2a) into the floating gate electrode FG or the semiconductor substrate SB.

In the first embodiment, the floating gate electrode FG and the semiconductor substrate SB are in contact with not the insulating film BL2 (BL2a) but the purified insulating film BL1 (BL1a), and thus, the diffusion of the impurities from the insulating film BL1 (BL1a) into the floating gate electrode FG or the semiconductor substrate SB can be suppressed or prevented.

Therefore, the insulating film BL (BLa) includes the insulating film BL1 (BL1a) and the insulating film BL2 (BL2a) on the insulating film BL1 (BL1a), thereby improving the reliability of the semiconductor device.

The insulating film BL1 and the insulating film BL2 are made of the same material (silicon oxide) as each other, and thus, the insulating film BL1 can be regarded as the lower portion of the insulating film BL made of silicon oxide while the insulating film BL2 can be regarded as the upper portion of the insulating film BL made of silicon oxide. The density (atom density) of the upper portion (insulating film BL2) of the insulating film BL is larger than the density (atom density) of the lower portion (insulating film BL1) of the insulating film BL. Thus, the thermal shrinkage rate of the upper portion (insulating film BL2) of the insulating film BL is smaller than the thermal shrinkage rate of the lower portion (insulating film BL1) of the insulating film BL. The wet etching rate of the upper portion (insulating film BL2) of the insulating film BL is smaller than the wet etching rate of the lower portion (insulating film BL1) of the insulating film BL.

The thickness of the insulating film BL2 is preferably larger than the thickness of the insulating film BL1. In other words, the formation thickness of the insulating film BL2a is preferably larger than the formation thickness of the insulating film BL1a. As described above, in the reflection of the fact that the density of the insulating film BL2 (BL2a) is larger than the density of the insulating film BL1 (BL1a), the thermal shrinkage rate of the insulating film BL2 (BL2a) is smaller than the thermal shrinkage rate of the insulating film BL1 (BL1a). Thus, when most of the thickness of the insulating film BL (BLa) is occupied by the thickness of the insulating film BL2 (BL2a) with the smaller thermal shrinkage rate, the thermal shrinkage rate of the entire insulating film BL (BLa) can be suppressed. That is, the thermal shrinkage rate of the insulating film BL2 (BL2a) thicker than the insulating film BL1 (BL1a) is smaller than the thermal shrinkage rate of the insulating film BL1 (BL1a), thereby efficiently suppressing the thermal shrinkage rate of the entire insulating film BL (BLa). Thereby, the stress caused by the thermal shrinkage of the insulating film BL (BLa) can be accurately suppressed, thereby further improving the reliability of the semiconductor device. The formation thickness of the insulating film BL1a can be set to, for example, about equal to or larger than 10 nm and equal to or smaller than 30 nm. The formation thickness of the insulating film BL2 a can be set to, for example, about equal to or larger than 40 nm and equal to or smaller than 70 nm.

The thickness T1 of the insulating film BL is the total of the thickness of the insulating film BL1 and the thickness of the insulating film BL2. Note that the thickness of the insulating film BL2 may be decreased by the etching in the steps of forming the metal silicide layer SL and then removing the metal film ME by wet etching. Thus, the thickness of the insulating film BL in the manufactured semiconductor device may be smaller than the total of the formation thickness of the insulating film BL1a and the formation thickness of the insulating film BL2a. The formation thickness of the insulating film BL1a and the formation thickness of the insulating film BL2a are preferably set such that the thickness T1 of the insulating film BL in the manufactured semiconductor device is equal to or larger than 40 nm.

A direction of stress of the insulating film BL1 (BL1a) and a direction of stress of the insulating film BL2 (BL2a) are preferably opposite each other. That is, it is preferable that stress of the insulating film BL1 (BL1a) is tensile stress while stress of the insulating film BL2 (BL2a) is compression stress or that stress of the insulating film BL1 (BL1a) is compression stress while stress of the insulating film BL2 (BL2a) is tensile stress. Thereby, stress of the insulating film BL1 (BL1a) and stress of the insulating film BL2 (BL2a) can be canceled by each other, and thus, stress of the entire insulating film BL (BLa) can be further suppressed. Therefore, the reliability of the semiconductor device can be further improved.

A direction of stress of the insulating film BL (BLa) and a direction of stress of the STI region 2 are preferably opposite each other. That is, it is preferable that stress of the STI region 2 is tensile stress while stress of the insulating film BL (BLa) is compression stress or that stress of the STI region 2 is compression stress while stress of the insulating film BL (BLa) is tensile stress. Thereby, stress of the STI region 2 and stress of the insulating film BL (BLa) can be canceled by each other, and thus, stress caused on the semiconductor substrate SB by the STI region 2 and the entire insulating film BL (BLa) can be suppressed. Therefore, the reliability of the semiconductor device can be further improved.

In the first embodiment, the activation annealing processing is preferably performed after forming the insulating film BL1a and before forming the insulating film BL2a. Thereby, the activation annealing processing is performed while the semiconductor substrate SB (the n-type semiconductor region H1, the n-type semiconductor region H2, and the n-type semiconductor region H3) is covered with the insulating film BL1a, and thus, the n-type impurities or the p-type impurities in the semiconductor substrate SB can be suppressed or prevented from being released outside the semiconductor substrate SB in the activation annealing processing. Further, the activation annealing processing is performed while the semiconductor substrate SB (the n-type semiconductor region H1, the n-type semiconductor region H2, and the n-type semiconductor region H3) is covered with the insulating film BL1a and the insulating film BL2a is not formed on the insulating film BL1a, and thus, the stress due to the insulating film BL2a can be suppressed from being caused on the semiconductor substrate SB in the activation annealing processing. Consequently, the stress caused on the semiconductor substrate SB in the activation annealing processing can be suppressed, thereby suppressing or preventing the formation of the crystal defects in the semiconductor substrate SB.

In the first embodiment, the activation annealing processing can be performed after forming the insulating film BL2a and before forming the photoresist pattern RP1. Thereby, the activation annealing processing is performed while the semiconductor substrate SB (the n-type semiconductor region H1, the n-type semiconductor region H2, and the n-type semiconductor region H3) is covered with the insulating film BLa, and thus, the n-type impurities or the p-type impurities in the semiconductor substrate SB can be suppressed or prevented from being released outside the semiconductor substrate SB in the activation annealing processing.

### SECOND EMBODIMENT

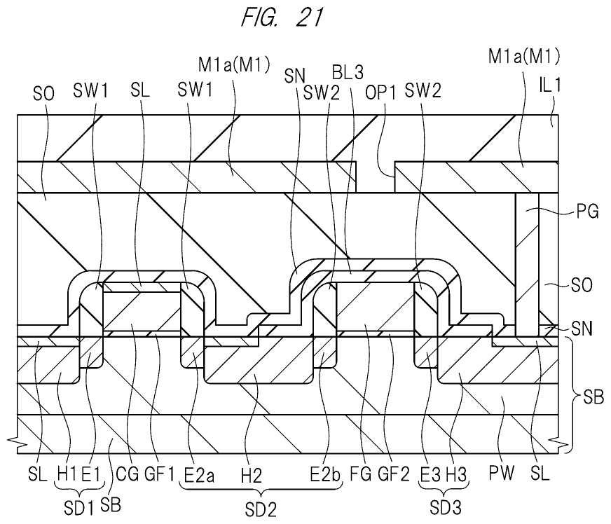

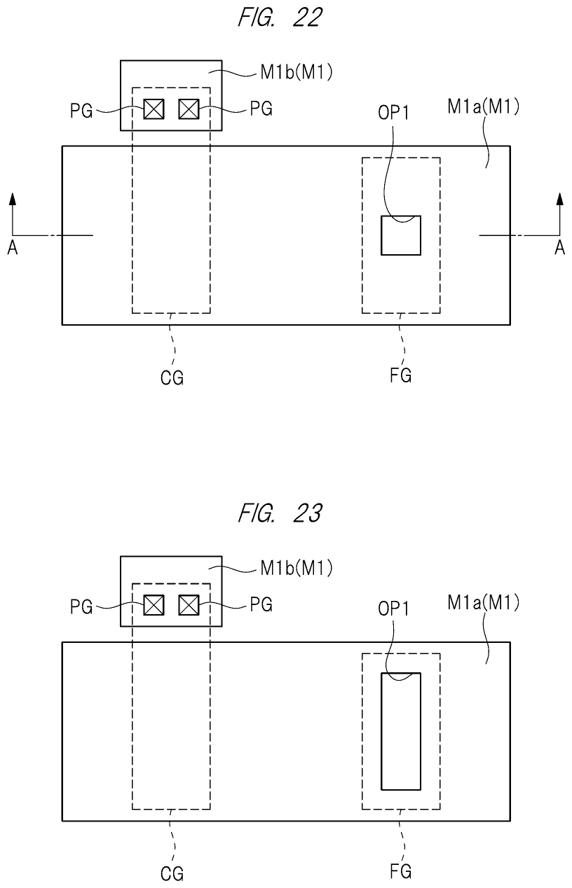

FIG. 21 is a cross-sectional view taken along the line A-A of FIG. 22.

A semiconductor device according to a second embodiment illustrated in FIGS. 21 and 22 is different from the semiconductor device according to the first embodiment illustrated in FIG. 1 in use of an insulating film BL3 instead of the insulating film BL and formation of a wiring M1a. In FIG. 21, an insulating film (interlayer insulating film) IL1 is formed on the insulating film SO to cover the wiring M1. Although illustration of the insulating film IL1 is omitted in FIG. 1, the insulating film IL1 is actually formed.

The insulating film (silicon oxide film) BL3 illustrated in FIG. 21 is made of silicon oxide. The insulating film BL3 is formed at the same position as that of the insulating film BL, and thus, the repetitive description thereof is omitted.

As described according to the first embodiment, since the hydrogen ions being caused in the insulating film SN (silicon nitride film) by the irradiation with the ultraviolet light onto the insulating film SN during the erasing operation in the nonvolatile memory may reach the floating gate electrode FG, there is the risk of the decrease in the charge holding property of the nonvolatile memory. The first embodiment and the second embodiment are different from each other in the countermeasure against this point.

In the first embodiment, the thickness of the insulating film BL interposed between the insulating film SN and the floating gate electrode FG is made large, thereby making difficulty in the reaching of the hydrogen ions caused in the insulating film SN to the floating gate electrode FG. And, the devisal is mage on the configuration of the insulating film BL in order to handle the potential failure caused by the large thickness of the insulating film BL.

In the second embodiment, an irradiation dose (irradiation area) of the ultraviolet light on the insulating film SN (silicon nitride film) is suppressed, thereby suppressing the amount (number) of hydrogen ions caused in the insulating film SN by the ultraviolet light, and correspondingly suppressing the amount (number) of hydrogen ions reaching the floating gate electrode FG.

Thus, the thickness of the insulating film BL3 corresponding to the insulating film BL in the second embodiment may be smaller than the thickness of the insulating film BL in the first embodiment. The insulating film BL3 may be made of a single-layer silicon oxide film.

In the second embodiment, a plurality of wirings M1 arranged on the insulating film SO include the wiring M1a and a wiring M1b. Each of the wiring M1a and the wiring M1b is made of a metal, and can be regarded as a metal film.

As illustrated in FIGS. 21 and 22, the wiring M1a is formed on the insulating film SO, and covers a part of the control gate electrode CG and the floating gate electrode FG in plan view. The wiring M1b is formed on the insulating film SO, and is electrically connected to the control gate electrode CG via the plug PG.

The wiring M1a partially overlaps the floating gate electrode FG in plan view. The floating gate electrode FG has a part overlapping the wiring M1a and the other part not overlapping the wiring M1a in plan view.

In FIG. 22, the outer periphery of the wiring M1a surrounds the floating gate electrode FG in plan view. That is, the outer periphery of the floating gate electrode FG is present within the outer periphery of the wiring M1a.

In FIGS. 21 and 22, the wiring M1a includes an opening OP1. The opening OP1 penetrates through the wiring M1a from the upper surface of the wiring M1a to the lower surface of the wiring M1a. The opening OP1 of the wiring M1a is included in the floating gate electrode FG in plan view. That is, the opening OP1 is present inside the outer periphery of the floating gate electrode FG in plan view. Thus, a part of the floating gate electrode FG overlaps the opening OP1 of the wiring M1a, and the other part of the floating gate electrode FG overlaps the wiring M1a in plan view. In other words, the floating gate electrode FG integrally has the part overlapping the wiring M1a in plan view and the part overlapping the opening OP1 of the wiring M1a in plan view. The entire opening OP1 of the wiring M1a is preferably overlap the floating gate electrode FG in plan view. The potential of the floating gate electrode FG is a floating potential. The wiring M1a is not electrically connected to the floating gate electrode FG via a conductor. Thus, the plug PG is not interposed between the floating gate electrode FG and the wiring M1a. No other wirings (in a layer upper than the wiring M1) included in the semiconductor device are preferably present at a position overlapping the opening OP1 of the wiring M1a in plan view.

In FIG. 21, the wiring M1a is electrically connected to the n-type semiconductor region H3 (n-type semiconductor region SD3) via the plug PG. A wiring other than the wiring electrically connected to the n-type semiconductor region H3 may be used for the wiring M1a. The wiring M1a may be electrically floating.

The ultraviolet light can pass through the insulating films used in the semiconductor device, but cannot pass through the metal films such as the wirings. Thus, the ultraviolet light can pass through the opening of the wiring M1a, but cannot pass through the metallic part of the wiring M1a. In the semiconductor device according to the second embodiment illustrated in FIGS. 21 and 22, when the erasing operation using the ultraviolet light in the nonvolatile memory is performed, the ultraviolet light having passed through the opening OP1 of the wiring M1a passes through the insulating film SO, the insulating film SN, and the insulating film BL3, and irradiates the floating gate electrode FG. Thereby, the electrons accumulated in the floating gate electrode FG are excited, thereby moving the electrons in the floating gate electrode FG to outside the floating gate electrode FG, and correspondingly bringing the nonvolatile memory into the erasing state. Since the floating gate electrode FG has the part not overlapping the wiring M1a in plan view, and thus, the floating gate electrode FG can be irradiated with the ultraviolet light.

In the erasing operation, the ultraviolet light can pass through the opening OP1 of the wiring M1a, but cannot pass through the wiring M1a itself. Thus, when the wiring M1a is present, the irradiation dose of the ultraviolet light on the insulating film SN can be made smaller than a case without the wiring M1a, since the ultraviolet light is shielded by the wiring M1a. That is, although the insulating film SN immediately below the opening OP1 of the wiring M1a is irradiated with the ultraviolet light, the insulating film SN immediately below the wiring M1a is not irradiated with the ultraviolet light. Therefore, in the erasing operation, the irradiation dose (irradiation area) of the ultraviolet light on the insulating film SN near the floating gate electrode FG can be made small, and thus, the amount (number) of hydrogen ions caused in the insulating film SN by the ultraviolet light can be suppressed, thereby suppressing the amount (number) of hydrogen ions reaching the floating gate electrode FG from the insulating film SN through the insulating film BL3 or the like. That is, since the floating gate electrode FG has the part overlapping the wiring M1a in plan view, the amount of hydrogen ions caused in the insulating film SN near the floating gate electrode FG can be suppressed. Thereby, the number of hydrogen ions present around the floating gate electrode FG can be suppressed, and thus, the charges (electrons, here) accumulated in the floating gate electrode FG can be suppressed or prevented from bonding with the hydrogen ions present around the floating gate electrode FG. Consequently, the unintentional decrease in the effective amount of charges (electrons) accumulated in the floating gate electrode FG can be suppressed or prevented, and thus, the charge holding property of the nonvolatile memory can be improved. Therefore, the reliability of the semiconductor device including the nonvolatile memory can be improved.

A modification example of the semiconductor device will be described.

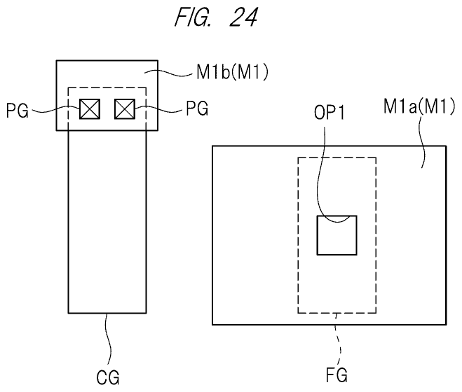

The plane dimension (plane area) of the opening OP1 of the wiring M1a illustrated in FIG. 23 is different from the plane dimension (plane area) of the opening OP1 of the wiring M1a illustrated in FIG. 22. For example, the plane dimension of the opening OP1 of the wiring M1a illustrated in FIG. 23 is larger than the plane dimension of the opening OP1 of the wiring M1a illustrated in FIG. 22.

The plane dimension of the opening OP1 of the wiring M1a can be set as needed. The plane dimension of the opening OP1 of the wiring M1a is preferably set such that the floating gate electrode FG is irradiated with an appropriate amount of ultraviolet light in the erasing operation. For example, the larger the plane dimension of the opening OP1 of the wiring M1a is, the larger the amount (area) of the ultraviolet light passing through the opening OP1 of the wiring M1a and irradiating the floating gate electrode FG in the erasing operation is. To the contrary, if the plane dimension of the opening OP1 of the wiring M1a is too large, the amount (area) of the ultraviolet light passing through the opening OP1 of the wiring M1a and irradiating the insulating film SN is made large, and thus, the amount (number) of hydrogen ions caused in the insulating film SN and supplied from the insulating film SN into the insulating film BL3 is made large.

Thus, the plane dimension of the opening OP1 of the wiring M1a may be set in consideration of an appropriate irradiation amount of the ultraviolet light on the floating gate electrode FG required for the erasing. Thereby, both the reliability of the erasing operation using the ultraviolet light in the nonvolatile memory and the improvement of the charge holding property of the nonvolatile memory can be achieved.

In the second embodiment, the case in which the number of the opening OP1 of the wiring M1a is one has been described. The number of the opening OP1 of the wiring M1a may be plural.

Another modification example of the semiconductor device according to the second embodiment will be described.

In FIG. 22, the wiring M1a overlaps not only the floating gate electrode FG but also a part of the control gate electrode CG in plan view. In FIG. 24, the wiring M1a overlaps the floating gate electrode FG but does not overlap the control gate electrode CG in plan view.

In the case of FIG. 22, the irradiation dose (irradiation area) of the ultraviolet light on the insulating film SN in the erasing operation can be made smaller than that in the case of FIG. 24. Thus, in the case of FIG. 22, the amount (number) of hydrogen ions caused in the insulating film SN by the ultraviolet light can be further made smaller than that in the case of FIG. 24, and thus, this case is advantageous in improving the charge holding property of the nonvolatile memory.

In the case of FIG. 24, the plane dimension (plane area) of the wiring M1a can be made smaller than that in the case of FIG. 22. Thus, the insulating film IL1 can be easily flattened.

For example, after the wiring M1a is formed, the insulating film IL1 is then formed on the insulating film SO to cover the wiring M1a, and then, the upper surface of the insulating film IL1 is polished by using a CMP method, thereby flattening the upper surface of the insulating film IL1. At this time, if the plane dimension of the wiring M1a is too large, there is a risk of decrease in the flatness of the upper surface of the insulating film IL1 in the CMP step of polishing the insulating film IL1. In the case of FIG. 24, since the plane dimension of the wiring M1a can be made small, thereby easily flattening the upper surface of the insulating film IL1 in the CMP step of polishing the insulating film IL1.

Still another modification example of the semiconductor device according to the second embodiment will be described.

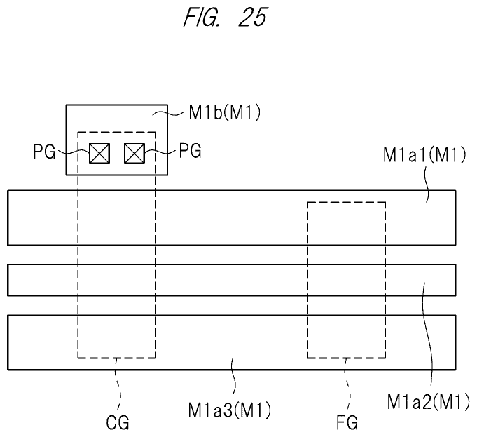

In the case of FIG. 25, a wiring M1a1, a wiring M1a2, and a wiring M1a3 are formed instead of the wiring M1a. Each of the wiring M1a1, the wiring M1a2, and the wiring M1a3 partially overlaps the floating gate electrode FG in plan view. The wiring M1a1 and the wiring M1a2 are adjacent to each other, the wiring M1a2 and the wiring M1a3 are adjacent to each other, and the wiring M1a2 is arranged between the wiring M1a1 and the wiring M1a3. The wiring M1a2 is, for example, a signal line.

In the case of FIG. 25, the floating gate electrode FG has a part overlapping the wiring M1a1, a part overlapping the wiring M1a2, a part overlapping the wiring M1a3, and a part overlapping none of the wiring M1a1, the wiring M1a2, and the wiring M1a3 in plan view. For example, the floating gate electrode FG is exposed from a gap between the wiring M1a1 and the wiring M1a2 and a gap between the wiring M1a2 and the wiring M1a3 in plan view.

In the erasing operation, the ultraviolet light can pass through the gap between the wiring M1a1 and the wiring M1a2 and the gap between the wiring M1a2 and the wiring M1a3, but cannot pass through the wiring M1a1 itself, the wiring M1a2 itself, and the wiring M1a3 itself. The ultraviolet light having passed through the gap between the wiring M1a1 and the wiring M1a2 and the ultraviolet light having passed through the gap between the wiring M1a2 and the wiring M1a3 pass through the insulating film SO, the insulating film SN, and the insulating film BL3, and irradiate the floating gate electrode FG, thereby bringing the nonvolatile memory into the erasing state. Since the floating gate electrode FG has the part overlapping none of the wiring M1a1, the wiring M1a2, and the wiring M1a3 in plan view, the floating gate electrode FG can be irradiated with the ultraviolet light.

Since the ultraviolet light is shielded by the wiring M1a1, the wiring M1a2, and the wiring M1a3 in the erasing operation, the irradiation dose of the ultraviolet light on the insulating film SN can be made small. Thus, the floating gate electrode FG has the part overlapping the wiring M1a1, the part overlapping the wiring M1a2, and the part overlapping the wiring M1a3 in plan view, thereby suppressing the amount of hydrogen ions caused in the insulating film SN near the floating gate electrode FG. Thereby, the number of hydrogen ions present around the floating gate electrode FG can be suppressed, and thus, the unintentional decrease in the effective amount of charges accumulated in the floating gate electrode FG can be suppressed or prevented.

### THIRD EMBODIMENT

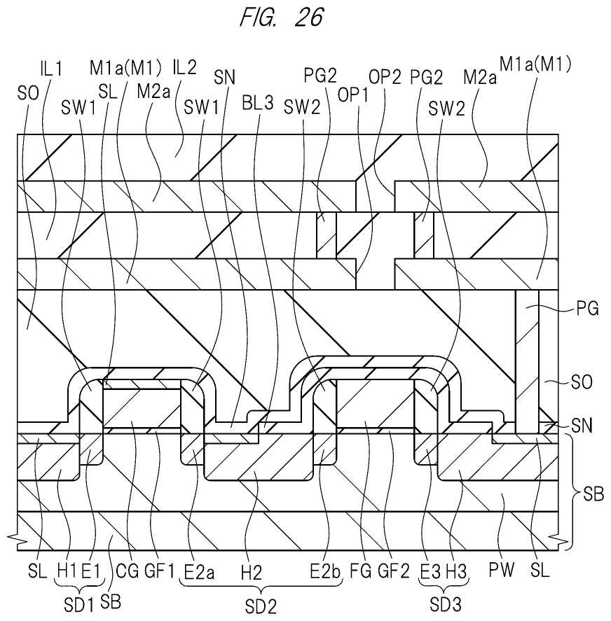

As illustrated in FIG. 26, a semiconductor device according to a third embodiment includes a wiring M2a formed on the insulating film IL1, and an insulating film (interlayer insulating film) IL2 formed on the insulating film IL1 to cover the wiring M2a. The wiring M2a is electrically connected to the wiring M1a via a plurality of conductive plugs PG2. Each plug PG2 is arranged between the wiring M1a and the wiring M2a, and penetrates through the insulating film IL1.

The semiconductor device according to the third embodiment illustrated in FIG. 26 is similar to the semiconductor device according to the second embodiment illustrated in FIG. 21 in the wiring M1a (M1), the insulating film SO, and the configurations below the insulating film SO.

As similar to the wiring M1a, the outer periphery of the wiring M2a surrounds the floating gate electrode FG in plan view. That is, the outer periphery of the floating gate electrode FG is present inside the outer periphery of the wiring M2a. The wiring M2a includes an opening OP2. The opening OP2 penetrates through the wiring M2a from the upper surface of the wiring M2a to the lower surface of the wiring M2a.

The opening OP2 of the wiring M2a overlaps the opening OP1 of the wiring M1a in plan view. Thus, as similar to the opening OP1 of the wiring M1a, the opening OP2 of the wiring M2a is included in the floating gate electrode FG in plan view.

In the semiconductor device according to the third embodiment illustrated in FIG. 26, in the erasing operation using the ultraviolet light in the nonvolatile memory, the ultraviolet light having passed through the opening OP2 of the wiring M2a and the opening OP1 of the wiring M1a passes through the insulating film SO, the insulating film SN, and the insulating film BL3, and irradiates the floating gate electrode FG. Thus, the ultraviolet light travelling in a direction substantially perpendicular to the main surface of the semiconductor substrate SB can pass through the opening OP2 of the wiring M2a and the opening OP1 of the wiring M1a and can enter the floating gate electrode FG. However, the ultraviolet light travelling in an oblique direction cannot pass through the opening OP1 of the wiring M1a after passing through the opening OP2 of the wiring M2a, and thus, cannot enter the floating gate electrode FG. The oblique direction described here corresponds to a direction oblique to the direction substantially perpendicular to the main surface of the semiconductor substrate SB.

Therefore, the ultraviolet light travelling in the oblique direction can be prevented from passing through the opening OP1 of the wiring M1a, traveling in the insulating film SO, and entering the insulating film SN. Thereby, the irradiation dose (irradiation area) of the ultraviolet light on the insulating film SN near the floating gate electrode FG can be further made smaller than that in the case without the wiring M2a. Consequently, the amount (number) of hydrogen ions caused in the insulating film SN by the ultraviolet light can be further suppressed, thereby further suppressing the amount (number) of hydrogen ions reaching the floating gate electrode FG from the insulating film SN through the insulating film BL3. Therefore, the charge holding property of the nonvolatile memory can be further improved.

The plugs PG2 can suppress or prevent the scattering of the ultraviolet light having passed through the opening OP2 of the wiring M2a and reflected by the wiring M1a, between the wiring M2a and the wiring M1a. Thus, the plurality of plugs PG2 are preferably arranged to surround the opening OP1 of the wiring M1a in plan view.

### FOURTH EMBODIMENT

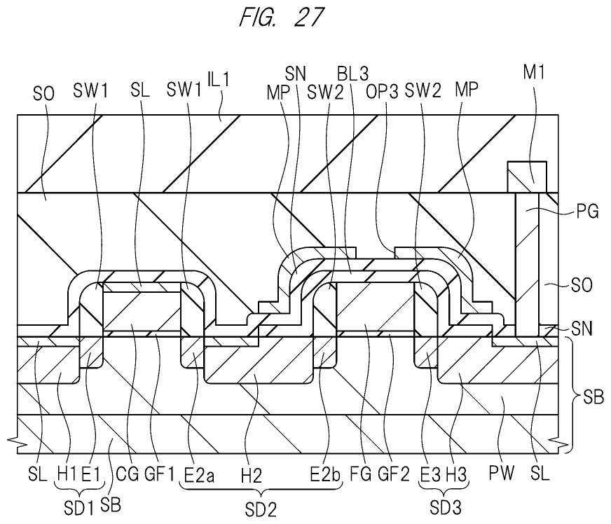

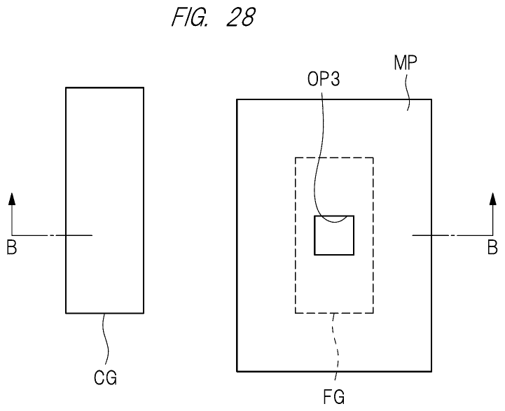

FIG. 27 is a cross-sectional view taken along the line B-B of FIG. 28.

A semiconductor device according to a fourth embodiment illustrated in FIGS. 27 and 28 is different from the semiconductor device according to the second embodiment illustrated in FIGS. 21 and 22 in use of a metal film (metal film pattern) MP instead of the wiring M1a.

As illustrated in FIG. 27, the metal film MP is formed on the insulating film SN. The insulating film SO is formed on the insulating film SN to cover the metal film MP. Other insulating film may be arranged between the metal film MP and the insulating film SN.

The metal film MP is made of, for example, a tungsten film. The metal film MP can be formed by, for example, forming the insulating film SN first, and then, forming the tungsten film, and patterning the tungsten film by using a photolithography technique and a dry etching technique. The insulating film SO is formed on the insulating film SN to cover the metal film MP after forming the metal film MP.

As illustrated in FIGS. 27 and 28, the metal film MP covers the floating gate electrode FG in plan view. The metal film MP is not electrically connected to the floating gate electrode FG via a conductor.

As illustrated in FIGS. 27 and 28, the outer periphery of the metal film MP surrounds the floating gate electrode FG in plan view. That is, the outer periphery of the floating gate electrode FG is present inside the outer periphery of the metal film MP.

As illustrated in FIGS. 27 and 28, the metal film MP includes an opening OP3. The opening OP3 penetrates through the metal film MP from the upper surface of the metal film MP to the lower surface of the metal film MP. The opening OP3 of the metal film MP is included in the floating gate electrode FG in plan view. That is, the opening OP3 is present inside the outer periphery of the floating gate electrode FG in plan view. Thus, a part of the floating gate electrode FG overlaps the opening OP3 of the metal film MP while the other part of the floating gate electrode FG overlaps the metal film MP in plan view. The entire opening OP3 of the metal film MP preferably overlaps the floating gate electrode FG in plan view. No wiring of the semiconductor device is preferably present at a position overlapping the opening OP3 of the metal film MP in plan view.

In the semiconductor device according to the fourth embodiment illustrated in FIGS. 27 and 28, in the erasing operation using the ultraviolet light in the nonvolatile memory, the ultraviolet light having passed through the opening OP3 of the metal film MP passes through the insulating film SN and the insulating film BL3, and irradiates the floating gate electrode FG. Thereby, the electrons in the floating gate electrode FG move outside the floating gate electrode FG, thereby bringing the nonvolatile memory into the erasing state.

The ultraviolet light can pass through the opening OP3 of the metal film MP, but cannot pass through the metal film MP itself. Thus, the insulating film SN immediately below the opening OP3 of the metal film MP is irradiated with the ultraviolet light. However, the insulating film SN immediately below the metal film MP is not irradiated with the ultraviolet light. Thus, in the case with the metal film MP, the irradiation dose of the ultraviolet light on the insulating film SN can be made smaller than that in the case without the metal film MP, since the ultraviolet light is shielded by the metal film MP. Since the irradiation dose (irradiation area) of the ultraviolet light on the insulating film SN near the floating gate electrode FG can be made small in the erasing operation, the amount (number) of hydrogen ions caused in the insulating film SN by the ultraviolet light can be suppressed, thereby suppressing the amount (number) of hydrogen ions reaching the floating gate electrode FG from the insulating film SN through the insulating film BL3. Thereby, the charge holding property of the nonvolatile memory can be improved. Therefore, the reliability of the semiconductor device including the nonvolatile memory can be improved.

In the foregoing, the invention made by the inventors of the present application has been concretely described based on the embodiments. However, it is needless to say that the present invention is not limited to the foregoing embodiments, and various modifications can be made within the scope of the present invention.

What is claimed is:

1. A semiconductor device comprising:
a semiconductor substrate;
a floating gate electrode of a first transistor for a memory, the floating gate electrode being formed on the semiconductor substrate via a first gate insulating film;
a gate electrode of a second transistor, the gate electrode being formed on the semiconductor substrate via a second gate insulating film;
a first sidewall spacer formed on a side surface of the floating gate electrode;
a second sidewall spacer formed on a side surface of the gate electrode;
a first insulating film covering the floating gate electrode; and
a silicon nitride film covering the floating gate electrode, the gate electrode, the first sidewall spacer, the second sidewall spacer, and the first insulating film,
wherein the first insulating film is made of silicon oxide,
wherein the first insulating film is interposed between an upper surface of the floating gate electrode and the silicon nitride film, and
wherein a density of an upper portion of the first insulating film is larger than a density of a lower portion of the first insulating film.

2. The semiconductor device according to claim 1,
wherein the first insulating film is made of a first silicon oxide film and a second silicon oxide film on the first silicon oxide film,
wherein the upper portion of the first insulating film is made of the second silicon oxide film, and
wherein the lower portion of the first insulating film is made of the first silicon oxide film.

3. The semiconductor device according to claim 2,
wherein a thickness of the first insulating film is equal to or larger than 40 nm.

4. The semiconductor device according to claim 3,
wherein a thickness of the second silicon oxide film is larger than a thickness of the first silicon oxide film.

5. The semiconductor device according to claim 2, further comprising:
an STI region formed in the semiconductor substrate,
wherein a direction of stress of the first silicon oxide film and a direction of stress of the second silicon oxide film are opposite each other, and
wherein a direction of stress of the first insulating film and a direction of stress of the STI region are opposite each other.

6. The semiconductor device according to claim 1,
wherein a metal silicide layer is formed on the gate electrode while a metal silicide layer is not formed on the floating gate electrode, and
wherein the silicon nitride film covers the metal silicide layer on the gate electrode.

7. The semiconductor device according to claim 6,
wherein the silicon nitride film is in contact with not the floating gate electrode but the metal silicide layer on the gate electrode.

8. The semiconductor device according to claim 1,
wherein the first insulating film covers the floating gate electrode and the first sidewall spacer.

9. The semiconductor device according to claim 1,
wherein a charge is accumulated in the floating gate electrode to store information.

10. The semiconductor device according to claim 1,
wherein a shrinkage rate of the upper portion of the first insulating film is smaller than a shrinkage rate of the lower portion of the first insulating film.

11. A method of manufacturing a semiconductor device, comprising steps of:
(a) preparing a semiconductor substrate;
(b) forming a floating gate electrode of a first transistor for a memory on a main surface of the semiconductor substrate via a first gate insulating film, and forming a gate electrode of a second transistor on the main surface of the semiconductor substrate via a second gate insulating film;
(c) forming a first sidewall spacer on a side surface of the floating gate electrode, and forming a second sidewall spacer on a side surface of the gate electrode;
(d) forming a first silicon oxide film on the main surface of the semiconductor substrate to cover the floating gate electrode, the gate electrode, the first sidewall spacer, and the second sidewall spacer, by using a thermal CVD method;
(e) forming a second silicon oxide film on the first silicon oxide film, by using a plasma CVD method;
(f) patterning a stacked film including the first silicon oxide film and the second silicon oxide film, thereby forming a first insulating film made of the patterned stacked film;
(g) after the step (f), forming a metal silicide layer on the gate electrode; and
(h) after the step (g), forming a silicon nitride film on the main surface of the semiconductor substrate to cover the floating gate electrode, the gate electrode, the first sidewall spacer, the second sidewall spacer, the metal silicide layer, and the first insulating film,
wherein the first insulating film covers the floating gate electrode, and
wherein in the step (h), the first insulating film is interposed between the floating gate electrode and the silicon nitride film.

12. The method of manufacturing the semiconductor device according to claim 11,
wherein after the step (h), a thickness of the first insulating film is equal to or larger than 40 nm.

13. The method of manufacturing the semiconductor device according to claim 12,
wherein a formation thickness of the second silicon oxide film in the step (e) is larger than a formation thickness of the first silicon oxide film in the step (d).

14. The method of manufacturing the semiconductor device according to claim 11,
wherein the step (g) is performed in a state in which the first insulating film covers the floating gate electrode while the gate electrode is exposed, and
wherein in the step (g), the metal silicide layer is formed on the gate electrode while the metal silicide layer is not formed on the floating gate electrode.

15. The method of manufacturing the semiconductor device according to claim 11, further comprising steps of:
(i) after the step (h), forming a second insulating film on the silicon nitride film;
(j) forming a contact hole penetrating through the second insulating film and the silicon nitride film; and
(k) after the step (j), forming a conductive plug in the contact hole.

16. The method of manufacturing the semiconductor device according to claim 11,
wherein a direction of stress of the second silicon oxide film formed in the step (e) and a direction of stress of the first silicon oxide film formed in the step (d) are opposite each other.

17. The method of manufacturing the semiconductor device according to claim 11, further comprising a step of:
(b1) after the step (b) and before the step (d), forming a first semiconductor region of a first conductive type, a second semiconductor region of the first conductive type, and a third semiconductor region of the first conductive type in the semiconductor substrate,
wherein the floating gate electrode is interposed between the first semiconductor region and the second semiconductor region in plan view,
wherein the gate electrode is interposed between the second semiconductor region and the third semiconductor region in plan view,
wherein the second semiconductor region is interposed between the floating gate electrode and the gate electrode in plan view,
wherein the first semiconductor region functions as a source region or a drain region of a first transistor,
wherein the second semiconductor region functions as a source region or a drain region of the first transistor, and functions as a source region or a drain region of a second transistor, and
wherein the third semiconductor region functions as a source region or a drain region of the second transistor.

18. The method of manufacturing the semiconductor device according to claim 11,
wherein the first insulating film covers the floating gate electrode and the first sidewall spacer.

19. The method of manufacturing the semiconductor device according to claim 11, further comprising a step of:
(d1) after the step (d) and before the step (e), performing an activation annealing processing on the semiconductor substrate.

20. A semiconductor device comprising:
a semiconductor substrate;
a floating gate electrode of a first transistor for a memory, the floating gate electrode being formed on the semiconductor substrate via a first gate insulating film;
a gate electrode of a second transistor, the gate electrode being formed on the semiconductor substrate via a second gate insulating film;
a first sidewall spacer formed on a side surface of the floating gate electrode;
a second sidewall spacer formed on a side surface of the gate electrode;
a first insulating film covering the floating gate electrode;
a silicon nitride film covering the floating gate electrode, the gate electrode, the first sidewall spacer, the second sidewall spacer, and the first insulating film; and
a metal film formed on the silicon nitride film,
wherein the first insulating film is made of silicon oxide,
wherein the first insulating film is interposed between an upper surface of the floating gate electrode and the silicon nitride film, and
wherein the metal film overlaps the floating gate electrode in plan view while the floating gate electrode has a portion not overlapping the metal film in plan view.
